(19) United States
(12) Patent Application Publication
(10) Pub. No.: US 2008/0277750 A1
(43) Pub. Date: Nov. 13, 2008

(54) Layout Method for Mask, Semiconductor Device and Method for Manufacturing the Same

(76) Inventors: SANG HEE LEE, Eumseong-gun (KR); Gab Hwan Cho, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/117,362

(22) Filed: May 8, 2008

(30) Foreign Application Priority Data
May 10, 2007 (KR) 10-2007-0045624

(51) Int. Cl. H01L 31/0232; H01L 31/18; G06F 17/50

(52) U.S. Cl. 257/432; 438/70; 716/21; 257/E31.127

(57) ABSTRACT

A mask layout method, semiconductor device and method for fabricating the same using a mask created according to the subject mask layout method are provided. The semiconductor device can include a microlens main pattern on a substrate and a microlens dummy pattern at a side of the microlens main pattern. The microlens dummy pattern can be formed in plurality using a mask created by the subject mask layout method. According to an embodiment of the subject mask layout method, a microlens dummy pattern can be created by forming a base dummy pattern and removing edge areas from the base dummy pattern. The microlens dummy pattern can be created to have a substantially circular shape. In one embodiment, the substantially circular shape can be an octagon.

### CROSS-REFERENCE TO RELATED APPLICATION

The present application claims the benefit under 35 U.S.C. §119 of Korean Patent Application No. 10-2007-0045624, filed May 10, 2007, which is hereby incorporated by reference in its entirety.

### BACKGROUND

In general, a semiconductor device has a multi-layer structure, in which each layer of the multi-layer structure is generally formed through a deposition process or a sputtering process, and then patterned through a lithography process.

However, various problems may occur due to differences in size and density of patterns formed on a substrate of the semiconductor device. To solve the above problems, methods of forming a dummy pattern together with a main pattern are being developed.

### BRIEF SUMMARY

Embodiments of the present invention provide a layout method for a mask, and a semiconductor device and method for manufacturing the same utilizing a mask formed according to the subject mask layout method.

An embodiment of the mask layout method provides a microlens dummy pattern.

According to embodiments of the subject mask layout method pattern uniformity can be ensured.

A mask layout method according to an embodiment of the present invention is capable of enhancing pattern density.

In addition, a mask layout method according to an embodiment of the present invention is capable of simplifying designing and manufacturing processes.

A semiconductor device according to an embodiment can include a microlens main pattern on a substrate, and a microlens dummy pattern on the substrate near a side of the microlens main pattern.

In addition, a method of manufacturing a semiconductor device according to an embodiment can include forming a microlens main pattern on a substrate, and forming a microlens dummy pattern at a side of the microlens main pattern.

Further, a layout method for a mask according to an embodiment includes forming a microlens main pattern in a main chip region, and forming a microlens dummy pattern in a region where the microlens main pattern is not formed.

### BRIEF DESCRIPTION OF THE DRAWINGS

FIG. 1 is a plan view of a semiconductor device according to an embodiment.

FIG. 2 is a cross-sectional view of a semiconductor device taken along line I-I′ of FIG. 1 according to an embodiment.

FIGS. 3A to 3C are schematic views for describing a layout method of a mask according to an embodiment.

### DETAILED DESCRIPTION

Hereinafter, a layout method for a mask, a semiconductor device, and a method for manufacturing the same according to embodiments of the present invention will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

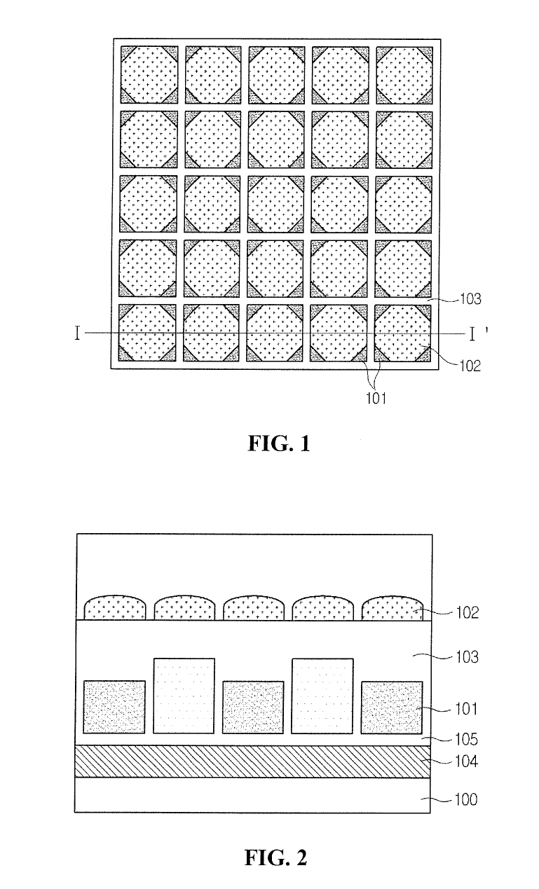

Referring to FIGS. 1 and 2, a semiconductor device according to an embodiment can include a microlens main pattern (not shown) formed on a substrate 100 of the semiconductor device, and a microlens dummy pattern 102 formed at a side of the microlens main pattern.

According to an embodiment, the microlens dummy pattern 102 is provided in a region where the microlens main pattern is not formed, so that pattern uniformity can be improved between a main pattern region and a dummy pattern region.

In addition, according to an embodiment, the microlens dummy pattern 102 can be formed to have a substantially circular shape. The substantially circular shape can be used to improve pattern uniformity between the main pattern region and the dummy pattern region. In one embodiment, the substantially circular shape of the microlens dummy pattern 102 can be an octagonal structure.

Although the microlens dummy pattern 102 is shown in the figures having the octagonal shape, this is for illustrative purposes only. The microlens dummy pattern 102 can be formed in a variety of shapes.

Hereinafter, a method of manufacturing the semiconductor device according to an embodiment will be described with reference to FIGS. 1 and 2.

A substrate 100 can be provided with various structures (not shown) according to a design, and a metal pattern 104 can be formed on the substrate 100. The metal pattern 104 can be the uppermost metal pattern, but embodiments are not limited thereto.

Next, an interlayer dielectric layer 105 can formed on the substrate 100 having the metal pattern 104. The interlayer dielectric layer 105 can have a single layer structure or a multi-layer structure.

Then, in certain embodiments, a color filter layer can be formed on the interlayer dielectric layer 105. The color filter layer can include a color filter main pattern (not shown) and a color filter dummy pattern 101. In one embodiment having a color filter layer, the color filter main pattern can include a red-green-blue (RGB) color filter main pattern formed by coating and patterning dyeable resist to filter light according to wavelengths of the light.

The RGB color filter main pattern includes red (R), green (G) and blue (B) color filters, which can be formed by selectively performing photolithography processes three times relative to red (R), green (G) and blue (B) color layers.

After forming the red (R), green (G) and blue (B) color filters, a UV exposure process can be performed to improve stability of the color filter layer surface.

Then, a planarization layer 103 can be formed on the color filter layer including the color filter main pattern and the color filter dummy pattern 101.

In an embodiment, the planarization layer 103 can be formed on the color filter main pattern to prepare the substrate for a microlens layer formed on the planarization layer 103 and to adjust the focal length.

In certain embodiments, a heat-treatment process can be performed to cure the planarization layer 103. In one embodiment, the heat-treatment process is performed at the temperature of about 150° C. to 300° C. to cure and stabilize the planarization layer 103.

Then a microlens main pattern (not shown) and a microlens dummy pattern 102 can be formed on the planarization layer 103. In one embodiment, the microlens main pattern and the microlens dummy pattern 102 can be formed sequentially using separate masks. In another embodiment, the microlens main pattern and the microlens dummy pattern 102 can be formed simultaneously.

According to embodiments of the present invention, the microlens dummy pattern 102 is inserted into a region where the microlens main pattern is not formed, so that pattern uniformity can be improved between a main pattern region and a dummy pattern region.

In addition, according to an embodiment, the microlens dummy pattern 102 has a substantially circular shape, so that pattern uniformity can be improved between the main pattern region and the dummy pattern region. In a specific embodiment, the substantially circular shape of the microlens dummy pattern 102 can include an octagonal structure. Of course, embodiments are not limited to the octagonal structure.

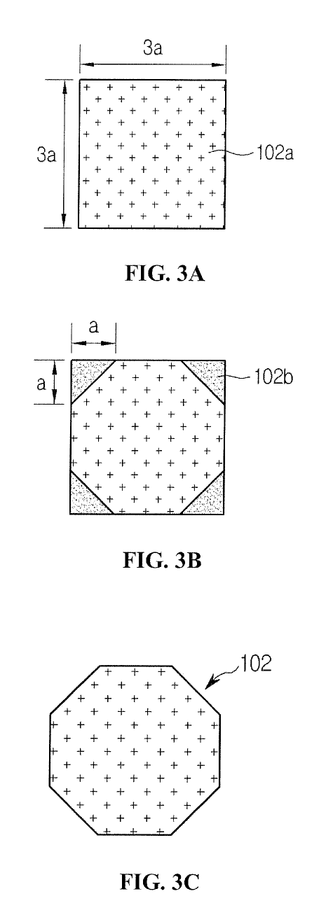

Hereinafter, a layout method for a mask according to an embodiment of the present invention will be described with reference to FIGS. 3A to 3C. A microlens main pattern (not shown) can be created on a main chip region (not shown) during a layout design with, for example, a layout software tool.

Then, a microlens dummy pattern 102 can be formed on a region where the microlens main pattern is not formed using the layout software tool.

First, referring FIG. 3A, according to one embodiment, a base dummy pattern 102a having a polygonal shape can be formed on a region where the microlens main pattern is not formed. The base dummy pattern 102a can have a regular polygonal shape. In a specific embodiment, the base dummy pattern 102a has a regular square shape, but embodiments are not limited thereto.

Referring to FIG. 3B, edge areas 102b can be defined at edges of the base dummy pattern 102a.

In one embodiment, the edge areas 102b can have right-angled isosceles triangular shapes, but embodiments are not limited thereto.

In a specific embodiment using light-angled isosceles triangular shapes, the lateral sides of the right-angled isosceles triangle, except for its hypotenuse, can have a length (a) corresponding to ⅓ of the length (3a) of one lateral side of the base dummy pattern 102a.

Then, referring to FIG. 3C, the edge areas 102b can be removed from the base dummy pattern 102a to form the microlens dummy pattern 102. Any known layout software tool can be used to accomplish this step.

As described above, according to an embodiment, the microlens dummy pattern having a substantially circular shape can be formed by using a base dummy pattern having a regular square shape, so that layout of the dummy pattern can be achieved with high speed and improved accuracy.

In addition, according to embodiments, the microlens dummy pattern is inserted into a region where the microlens main pattern is not formed, so that pattern uniformity can be improved between a main pattern region and a dummy pattern region.

Further, according to an embodiment, the microlens dummy pattern can be produced by simply removing edge regions of a regular square shape, so that data load required for the layout of the dummy pattern can be reduced.

According to an embodiment, each pattern can have a uniform CD (critical dimension) due to the uniformity of the pattern.

Further, according to an embodiment the layout process and the manufacturing process can be simplified.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a microlens main pattern on a substrate; and
a microlens dummy pattern on the substrate at a side of the microlens main pattern.

2. The semiconductor device according to claim 1, further comprising a color filter dummy pattern provided on the substrate below the microlens dummy pattern.

3. The semiconductor device according to claim 1, wherein the microlens dummy pattern has a substantially circular shape.

4. The semiconductor device according to claim 3, wherein the microlens dummy pattern has an octagonal shape.

5. A method of manufacturing a semiconductor device, comprising:
forming a microlens main pattern on a substrate; and
forming a microlens dummy pattern on the substrate at a side of the microlens main pattern.

6. The method according to claim 5, further comprising forming a color filter dummy pattern before the forming of the microlens main pattern and the forming of the microlens dummy pattern.

7. The method according to claim 5, wherein the microlens dummy pattern is formed to have a substantially circular shape.

8. The method according to claim 7, wherein the microlens dummy pattern is formed to have an octagonal shape.

9. The method according to claim 5, wherein the forming of the microlens main pattern and the forming of the microlens dummy pattern are simultaneously performed.

10. The method according to claim 5, wherein the forming of the microlens main pattern and the forming of the microlens dummy pattern are performed in separate steps.

11. A layout method for a mask, comprising:
forming a microlens main pattern in a main chip region; and
forming a microlens dummy pattern in a region where the microlens main pattern is not formed.

12. The method according to claim 11, wherein forming the microlens dummy pattern comprises:
forming a base dummy pattern in the region where the microlens main pattern is not formed; and
removing edge areas from the base dummy pattern to form the microlens dummy pattern.

13. The method according to claim 12, wherein the base dummy pattern is a polygonal shape.

14. The method according to claim 13, wherein the base dummy pattern is a regular square shape.

15. The method according to claim 12, wherein removing the edge areas from the base dummy pattern comprises:
defining the edge areas of the base dummy pattern; and
removing the edge areas from the base dummy pattern using a software layout tool.

16. The method according to claim 15, wherein the edge areas have right-angled isosceles triangular shapes.

17. The method according to claim 16, wherein lateral sides of the right-angled isosceles triangle, except for its hypotenuse, have a length which corresponds to ⅓ length of one lateral side of the base dummy pattern.
